(19) United States
(12) Patent Application Publication
(10) Pub. No.: US 2025/0164580 A1
(43) Pub. Date: May 22, 2025

(54) METHODS AND APPARATUSES FOR TESTING ELECTRICAL CONNECTIONS OF A SUBSTRATE

(71) Applicant: Applied Materials, Inc., Santa Clara, CA (US)

(72) Inventors: Axel WENZEL, Augsburg (DE); Ludwig LEDL, Gröbenzell (DE); Bernhard G. MUELLER, Finsing (DE)

(21) Appl. No.: 18/839,597

(22) PCT Filed: Apr. 5, 2022
(86) PCT No.: PCT/EP2022/058995

§ 371 Date: Aug. 19, 2024

(51) Int. Cl. G01R 31/66

(52) U.S. Cl. CPC G01R 31/66

(57) ABSTRACT

A method for testing electrical connections of a substrate is described, the substrate having a first surface contact and a first electrical connection extending from the first surface contact. The method includes: (a) discharging the first surface contact by focusing and deflecting a first electron beam having a first electron energy on the first surface contact; (b) charging the first surface contact by focusing and deflecting a second electron beam having a second electron energy different from the first electron energy on the first surface contact; and (c) inspecting the first electrical connection by detecting signal electrons emitted from the substrate. Further described are apparatuses for testing electrical connections of a substrate using two electron beams of different electron energies in accordance with the methods described herein.

### FIELD

The present disclosure relates to methods and apparatuses for testing electrical connections extending through a substrate. More particularly, embodiments described herein relate to the contactless testing of electric interconnections in a substrate using an electron beam, particularly for identifying and characterizing defects such as shorts, opens, and/or leakages via voltage contrast measurements.

### BACKGROUND

In many applications, it is necessary to inspect a substrate to monitor the quality of the substrate. For example, glass substrates on which layers of coating material are deposited are manufactured for the display market. Since defects may occur during the processing of the substrates, e.g. during the coating of the substrates, an inspection of the substrate for reviewing the defects and for monitoring the quality of the displays may be beneficial.

Further, semiconductor substrates and printed circuits boards for the manufacture of complex microelectronic or micro-mechanic components are typically tested before, during, and/or after manufacturing for determining defects, such as shorts or opens, in metal paths and interconnects provided at the substrate. For example, substrates for the manufacture of complex microelectronic devices may include a plurality of interconnect paths meant for connecting semiconductor chips that are to be mounted on the substrate. Devices to be tested may further include, for example, thin film transistors (TFTs), connection networks, transistors, pixels of a display, and other components.

Various methods for testing such components are known. For example, contact pads of a component to be tested may be mechanically contacted with a contact probe, in order to determine whether the component is defective or not. However, since the components and the contact pads are becoming smaller and smaller due to the progressing miniaturization of components, contacting the contact pads with a contact probe may be difficult, and there may even be a risk that the device being tested gets damaged during the testing.

It is also possible to contactlessly probe a component to be tested, e.g., with an electron beam of an electron beam testing column (EBT column). Electron beam testing can be used to monitor defects of electrical connections of a substrate. In EBT testing, certain voltages are applied to components to be tested, and a primary electron beam is used to generate signal electrons that are emitted from the substrate and that allow conclusions about the integrity of the components. However, conventional e-beam testing methods may not be suitable for testing advanced microelectronic components, considering the increasing number of smaller and smaller components to be tested per substrate in a short time interval, while maintaining a high throughput.

Accordingly, it would be beneficial to provide testing methods and testing apparatuses that are suitable for reliably and quickly testing complex microelectronic devices.

### SUMMARY

In light of the above, methods and apparatuses for testing electrical connections of a substrate are provided according to the independent claims. Further aspects, advantages, and beneficial features are apparent from the dependent claims, the description, and the accompanying drawings.

According to one aspect, a method for testing electrical connections of a substrate is provided, the substrate having a first surface contact and a first electrical connection extending from the first surface contact. The method includes discharging (a) the first surface contact by focusing and deflecting a first electron beam having a first electron energy on the first surface contact, charging (b) the first surface contact by focusing and deflecting a second electron beam having a second electron energy different from the first electron energy on the first surface contact, and inspecting (c) the first electrical connection by detecting signal electrons emitted from the substrate.

In some embodiments, the substrate is an advanced packaging substrate (AP substrate) or a panel-level-packaging substrate (PLP substrate).

In some embodiments, discharging (a) is conducted before charging (b). In some embodiments, discharging (a) is additionally or alternatively conducted after inspecting (c). In some embodiments, discharging (a) is conducted before charging (b) and after inspecting (c). In other words, the discharging (a) of the first surface contact with the first electron beam may be conducted before the charging (b) of the first surface contact with the second electron beam, such that a substantially uncharged first surface contact having a defined electric potential can be charged in the charging phase (b). Alternatively or additionally, the discharging (a) of the first surface contact with the first electron beam may be conducted after the charging and inspection. Accordingly, after the inspection, the first surface contact can be brought back to a defined electric potential by discharging (a) the first surface contact with the first electron beam.

Charging (b) and inspecting (c) can be conducted simultaneously, for example by detecting a secondary electron signal emitted by the substrate as a function of time during the charging (b). Alternatively, the inspecting (c) can be conducted after the charging (b), for example by probing the first surface contact and/or by probing one or more further surface contacts with the second electron beam or with the first electron beam after the charging (c).

According to another aspect, an apparatus that is configured for testing electrical connections of a substrate in accordance with any of the methods described herein is provided.

An apparatus for testing electrical connections of a substrate as described herein may include: a vacuum chamber that houses a stage for placement of a substrate, a first electron source configured to generate a first electron beam having a first electron energy, a second electron source configured to generate a second electron beam having a second electron energy different from the first electron energy, a controller configured to control the apparatus such that: in a discharging phase (a), the first electron beam is focused and deflected on the first surface contact to discharge the first surface contact, in a charging phase (b), the second electron beam is focused and deflected on the first surface contact to charge the first surface contact, and a first electrical connection connected to the first surface contact is inspected by detecting signal electrons emitted from the substrate with an electron detector during or after the charging phase (b).

According to a further aspect, an apparatus for testing electrical connections of a substrate is provided, including: a vacuum chamber that houses a stage for placement of a substrate, a first electron source configured to generate a first electron beam having a first electron energy, a second electron source configured to generate a second electron beam having a second electron energy different from the first electron energy, a focusing lens arrangement for focusing the first electron beam on the substrate in a discharging phase and for focusing the second electron beam on the substrate in a charging phase, a beam deflector arrangement for deflecting the first electron beam on a first surface contact of the substrate to discharge the first surface contact in the discharging phase and for deflecting the second electron beam on the first surface contact to charge the first surface contact in the charging phase, an electron detector for detecting signal electrons emitted from the substrate, and an analysis unit for inspecting a first electrical connection connected to the first surface contact based on the signal electrons, particularly via voltage contrast measurements.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus and methods for manufacturing the apparatuses and devices described herein. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic sectional view of an apparatus for testing electrical connections of a substrate according to embodiments described herein;

FIG. 2 shows a schematic sectional view of an apparatus for testing electrical connections of a substrate according to embodiments described herein;

FIGS. 3A-D schematically illustrate a testing method according to embodiments described herein; and

FIG. 4 shows a flowchart of a method of testing electrical connections of a substrate according to embodiments described herein.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to same components. Only the differences with respect to the individual embodiments are described. The structures shown in the drawings are not necessarily depicted true to scale but rather serve the better understanding of the embodiments.

The complexity of packaging substrates has been increasing for years, with the aim of reducing the space requirements of semiconductor packages. A conventional semiconductor package is manufactured from a semiconductor wafer before being diced and packaged. The semiconductor package can then be mounted, together with other microelectronic components, on a printed circuit board (PCB).

For reducing the manufacturing costs, advanced packaging techniques were proposed, such as 2.5D ICs, 3D-ICs, and wafer-level packaging (WLP), e.g. fan-out WLP. In WLP techniques, the integrated circuit is packaged before dicing, while still being part of the wafer. Accordingly, the resulting package has practically the same size as the wafer.

“2.5D integrated circuits” (2.5D ICs) and “3D integrated circuits” (3D ICs) combine multiple dies in a single integrated package. Here, two or more unpackaged dies are placed on a packaging substrate, e.g. on a silicon interposer. In 2.5D ICs, the dies are placed on the packaging substrate side-by-side, whereas in 3D ICs at least some of the dies are placed on top of each other. The assembly can be packaged as a single component, which reduced costs and size as compared to a conventional 2D circuit board assembly. An advanced packaging (AP) substrate provides device-to-device electrical interconnection paths on or within a wafer, such as a silicon wafer. For example, an AP substrate may include Through Silicon Vias (TSVs), e.g., provided in a silicon interposer, or other conductor lines extending through the AP substrate. A panel-level-packaging (PLP) substrate is typically provided from a compound material, for example material of a printed circuit board (PCB) or another compound material, including, for example ceramics and glass materials.

A packaging substrate typically includes a plurality of device-to-device electrical interconnect paths meant for providing electrical connections between the dies that are to be placed on the packaging substrate. The device-to-device electrical interconnect paths may extend through a body of the packaging substrate in a complex connection network, vertically (perpendicular to the surface of the packaging substrate) and/or horizontally (parallel to the surface of the packaging substrate) with end points (referred to herein as surface contacts) exposed at the substrate surface.

In order to further reduce manufacturing costs, panel-level-substrates are manufactured that are configured for the integration of a plurality of devices (e.g., chips/dies that may be heterogeneous, e.g. may have different sizes and configurations) in a single integrated package. A panel-level substrate typically provides chip sites for a plurality of chips/dies to be placed on a surface thereof, e.g. on one side thereof or on both sides thereof, as well as a plurality of device-to-device electrical interconnect paths extending through a body of the packaging substrate. Notably, the size of a panel-level-substrate is not limited to the size of a wafer. For example, a panel-level-substrate may be rectangular or have another shape. Specifically, a panel-level-substrate may provide a surface area larger than the surface area of a typical wafer, e.g., 1000 cm² or more. For example, the panel-level substrate may have a size of 30 cm×30 cm or larger, 60 cm×30 cm or larger, 60 cm×60 cm or larger, or larger than that.

Conventional testing apparatuses may not be adapted or suitable for the testing of advanced packaging substrates due to the geometry and density of the surface contacts and/or due to the size of the packaging substrate which may be different from the size of conventional dies or printed circuit boards. The present disclosure relates to methods and apparatuses for testing substrates with a plurality of densely arranged surface contacts and a plurality of electrical connections extending between two or more surface contacts, respectively. In particular, the methods and apparatus described herein may be suitable for testing packaging substrates that are configured for the integration of a plurality of devices in one integrated package, and that may include at least one device-to-device electrical interconnect path extending between a first surface contact and at least one second surface contact.

A “surface contact” may be understood as an end point of an electrical interconnect path (also referred to herein as an “electrical connection”) that is exposed at a surface of the substrate, such that an electron beam can be directed on the surface contact for contactlessly charging or probing the surface contact. A surface contact may be meant for electrically contacting a chip/die that is to be placed on the surface of the substrate, e.g. via soldering. For example, a surface contact may be configured as a solder bump.

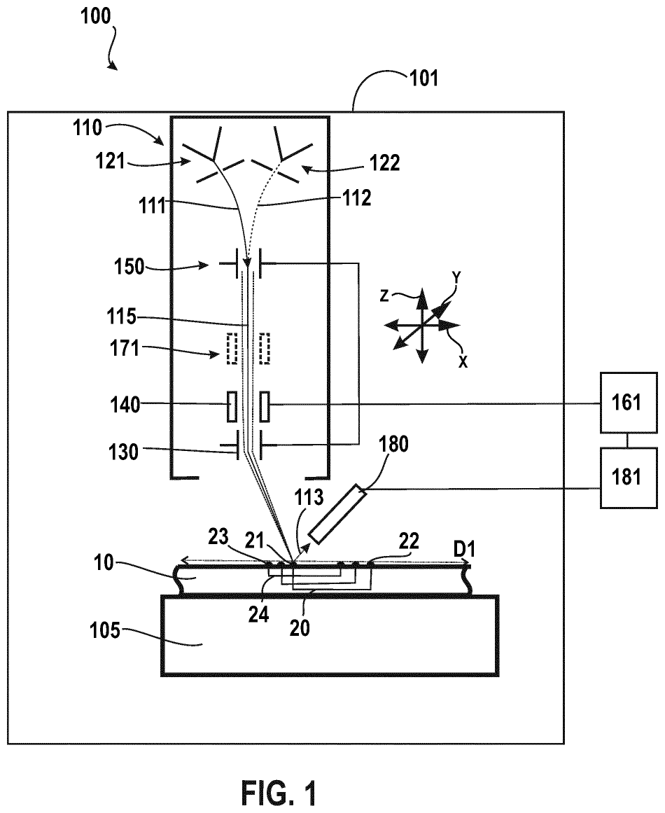

FIG. 1 shows an apparatus 100 for testing micro-electronic connections, such as interconnect paths and/or vias in a substrate 10 according to embodiments described herein in a schematic sectional view. The apparatus 100 includes a vacuum chamber 101 that may be a testing chamber specifically configured for testing or that may be one vacuum chamber of a larger vacuum system, e.g. a processing chamber of a substrate manufacturing or processing system. For example, the apparatus may be configured as an in-line inspection apparatus that is integrated in a substrate processing system.

As it is schematically depicted in FIG. 1, the substrate 10 includes a first surface contact 21 and a first electrical connection 20 extending from the first surface contact 21 through the substrate, e.g. to one or more second surface contacts 22 that may be provided on the same surface of the substrate as the first surface contact 21. The substrate 10 may include a plurality of surface contacts and a plurality of electrical connections extending from the plurality of surface contacts, for example 1.000 or more electrical connections, particularly 10.000 or more electrical connections, or even 100.000 or more electrical connections. The plurality of electrical connections extending from the plurality of surface contacts may be tested according to methods described herein.

In some embodiments, which can be combined with other embodiments described herein, one or more electrical connections extending between surface contacts on different sides of the substrate are inspected. In yet further embodiments, a first plurality of electrical connections extending between surface contacts on a first side of the substrate, a second plurality of electrical connections extending between surface contacts on a second side of the substrate, and/or a third plurality of electrical connections extending between surface contacts on different sides of the substrate are inspected. For example, one or more electron beam columns may be arranged on both sides of the substrates (not shown in the figures), such that surface contacts on both sides of the substrate can be charged and/or discharged for inspecting and testing the respective electrical connections.

Returning to FIG. 1, the apparatus 100 includes a first electron source 121 configured to generate a first electron beam 111 having a first electron energy and a second electron source 122 configured to generate a second electron beam 112 having a second electron energy different from the first electron energy, particularly higher than the first electron energy.

The apparatus further includes a controller 161 configured to control the apparatus 100 such that, in a discharging phase (a), the first electron beam 111 is focused and deflected on the first surface contact 21 to discharge the first surface contact, in a charging phase (b), the second electron beam 112 is focused and deflected on the first surface contact 21 to charge the first surface contact, and the first electrical connection 20 extending from the first surface contact 21 is inspected by detecting signal electrons emitted from the substrate with an electron detector 180 during or after the charging phase (b).

The discharging phase (a) and the charging phase (b) are conducted one after the other utilizing the first electron beam for discharging and the second electron beam for charging of the first surface contact. On the other hand, the charging phase (b) and the inspection (c) can also be conducted at the same time (i.e., by simultaneously charging and inspecting), specifically by detecting and analyzing the secondary electron signal that is emitted by the substrate as a function of time during the charging (b). It is also possible to conduct the charging and the inspection one after the other, namely by first charging the first surface contact with the second electron beam and then inspecting the first electrical connection by probing the first surface contact and/or further surface contacts with the first or second electron beam.

In some embodiments, which can be combined with other embodiments described herein, the first electron energy of the first electron beam 111 is lower than the second electron energy of the second electron beam 112. The “electron energy” of an electron beam relates to the (mean) energy of the electrons of the electron beam propagating toward the substrate. In particular, the first electron energy of the first electron beam 111 may be 1 keV or more and 3 keV or less, particularly about 1.5 keV, and/or the second electron energy of the second electron beam 112 may be 5 keV or more and 15 keV or less, particularly about 10 keV.

In some implementations, the first electron energy of the first electron beam 111 may be below a neutral charging point and the second electron energy of the second electron beam 112 may be above a neutral charging point. A “neutral charging point” as used herein refers to an electron energy of an electron beam that does not change the charges on an essentially uncharged surface contact when the electron beam impinges thereon, because the amount of signal electrons emitted from the substrate upon impingement essentially corresponds to the amount of electrons transferred to the surface contact by the electron beam. The neutral charging point may correspond to an electron energy of an electron beam of about 2 keV.

If the first electron beam 111 having an electron energy (such as 1.5 keV) below the neutral charging point impinges on a surface contact, the amount of signal electrons leaving the substrate is typically larger than the amount of electrons transferred to the substrate by the first electron beam 111, e.g. because the impinging electrons have a high probability of generating secondary electrons (SEs) that leave the substrate. Accordingly, negative charges are removed from the surface contact and the surface contact, together with the electrical connection extending therefrom, can be discharged. “Discharging” as used herein particularly relates to the removal of negative charges, i.e. electrons, that have accumulated on the surface contact.

If the second electron beam 112 having an electron energy (such as 10 keV) above the neutral charging point impinges on a surface contact, the amount of signal electrons leaving the substrate is typically smaller than the amount of electrons transferred to the substrate by the second electron beam 112, e.g. because high-energy electrons have a reduced probability of leaving the substrate or generating secondary electrons that leave the substrate. Accordingly, negative charges are applied to the surface contact, such that the surface contact, together with the electrical connection extending therefrom, is (negatively) charged. “Charging” as used herein particularly relates to the application of negative charges, i.e. electrons, to a surface contact to cause a predetermined electric potential of the surface contact.

Since the first electron beam 111 and the second electron beam 112 have different electron energies, particularly below and above the neutral charging point, the first electron beam 111 can be used for removing electrons, i.e. for discharging the surface contact, and the second electron beam 112 can be used for applying electrons, i.e. for charging the surface contact to a predetermined potential.

An electrical connection of a substrate can be inspected by charging the electrical connection, for example by directing an electron beam on a first surface contact that is electrically connected to the electrical connection, until the electrical connection is provided on a predetermined electric potential through the charging. After the charging of the electrical connection, one or more second surface contacts that are electrically connected to the first surface contact via the electrical connection are provided on the same electric potential as the first surface contact, if the electrical connection is not defective. The electric potential of the one or more second surface contacts can be probed, for example by directing the electron beam on the one or more second surface contacts and measuring an electron energy, an SE signal yield and/or a signal strength of emitted signal electrons. For example, the number of emitted signal electrons will be higher, if the probed surface contact is provided on a negative potential, i.e. is charged. Such so-called voltage contrast measurements allow the determination of defective electric connections of a substrate by probing surface contacts of charged electrical connections.

However, the density of surface contacts on a substrate has been increasing over the last years, such that it may be difficult to negatively charge a specific surface contact to a predetermined electric potential using an electron beam. For example, previously present charges on a surface contact (e.g., charges that are originally present on the sample and/or charges applied during a preceding measurement of a neighboring surface contact) may negatively affect the measurement accuracy, since charging of a pre-charged surface contact over a predetermined time period may not lead to a predetermined electric potential of the surface contact. Further, charges that are present on neighboring surface contacts may negatively affect the measurement accuracy, since said charges can deflect the signal electrons, such that only a portion thereof will reach the electron detector. Previously present charges on neighboring surface contacts can also negatively affect the probing electron beam impinging on a surface contact, which may result in a positioning inaccuracy and will not allow the testing of small surface contacts.

In order to solve the abovementioned problems, according to embodiments described herein, the first electron beam 111 having the first electron energy is used for discharging the first surface contact 21 before the charging thereof with the second electron beam 112 and/or after the inspection. The discharging of the first surface contact 21 in the discharging phase, i.e. the removal of negative charges that may be present on the first surface contact 21, can bring the first surface contact 21 to a defined state with a low electric potential or a zero electric potential before and/or after the testing. “Discharging” does not necessarily mean that the electric potential of the respective surface contact is brought to zero in relation to ground potential. Rather, the electric potential may be brought to a defined (low) voltage value that may allow to start the subsequent charging phase from a defined electric potential.

In some embodiments, the discharging (a) of a surface contact with the first electron beam may be conducted before the charging (b) of the surface contact with the second electron beam. This allows to start the charging phase (b) from a defined electric potential, which improves the measurement accuracy.

Alternatively or additionally, the discharging (a) of a surface contact with the first electron beam may be conducted after the inspecting (c). This allows to bring the surface contact back to a defined (low) electric potential after charging and inspection, such that subsequent measurements on neighboring surface contacts are not negatively affected by charges that may be left on a surface contact after the inspection.

In some embodiments, which can be combined with other embodiments described herein, the discharging (a) is conducted on the first surface contact before the charging (b), and the discharging (a) is again conducted on the first surface contact after the inspection (c). The measurement accuracy can be improved both for the test of the first electrical connection as well as for subsequent tests of neighboring electrical connections. In other words, the discharging (a), the charging (b), and the inspection (c) may be conducted in the following sequence: (a), (b)+(c), and again (a), said sequence being used for the test of each electrical connection of a plurality of electrical connections, “(b)+(c)” expressing that (b) and (c) can be conducted subsequently or simultaneously.

In some embodiments, which can be combined with other embodiments described herein, the substrate includes a plurality of surface contacts and a plurality of electrical connections extending from the plurality of surface contacts, e.g. 1.000 or more electrical connections or 10.000 or more electrical connections that are to be tested. The discharging (a), the charging (b), the inspection (c), and optionally again the discharging (a) may be conducted for each surface contact of the plurality of surface contacts for inspecting the plurality of electrical connections extending from the plurality of surface contacts.

For example, after the inspection of the first electrical connection 20, a second electrical connection 24 extending from a third surface contact 23 of the substrate may be tested as follows: Discharging the third surface contact 23 by focusing and deflecting the first electron beam 111 on the third surface contact 23, charging the third surface contact 23 by focusing and deflecting the second electron beam 112 on the third surface contact 23, and inspecting the second electrical connection 24 by detecting signal electrons emitted from the substrate during and/or after the charging. The discharging of the third surface contact 23 by focusing and deflecting the first electron beam 111 thereon may be conducted before the charging and/or after the inspecting. The method may then proceed by testing the other electrical connections analogously, particularly 1.000 or more electrical connections in succession by deflecting and focusing the first and second electron beams on respective surface contacts that extend from the plurality of electrical connections.

According to the embodiments described herein, the first electron beam 111 and the second electron beam 112 are subsequently focused on the first surface contact, particularly with a focusing lens arrangement 140. Specifically, the focusing lens arrangement 140 may be configured to focus a selected one of the first and second electron beams on the substrate. For example, the spot diameter of the first electron beam 111 and/or of the second electron beam 112 being focused on the substrate may be 10 μm or less, particularly 1 um or less. Accordingly, different from an UV light source or an electron floodgun which are typically used for charge removal from a substrate in other applications, the first electron beam 111 is focused on the substrate to specifically discharge a predetermined surface contact in a targeted way. A targeted charge removal from only a region of interest, e.g. from a specific surface contact currently under test, is enabled. Repeatedly discharging large substrate areas with an unfocused beam, such as with a floodgun, takes a substantial amount of time. The present disclosure enables a targeted and quick charge removal from a specific surface contact under test, accelerating the testing and improving the measurement accuracy.

According to embodiments described herein, the first electron beam 111 and the second electron beam 112 are deflected on the first surface contact, particularly with a beam deflector arrangement 130. For example, the beam deflector arrangement 130 may be configured to deflect a selected one of the first and second electron beams on a predetermined position on the substrate, such as on the first surface contact or on another surface contact. The beam deflector arrangement 130 may be an electrostatic beam deflector arrangement and/or a magnetic beam deflector arrangement configured to deflect the first electron beam 111 or the second electron beam 112 to a predetermined position on the substrate surface, wherein the substrate surface is provided in an x-y-plane. The beam deflector arrangement 130 may allow a beam deflection in two directions, i.e. in x-direction and in y-direction, such that the first and second electron beams can be deflected to arbitrary predetermined positions in the x-y-plane, where the plurality of surface contacts are distributed.

In some embodiments, the deflection area provided by the beam deflector arrangement 130 may be at least 9 cm² on the substrate surface for the first electron beam 111 and for the second electron beam 112. In particular, the beam deflector arrangement 130 may provide an overlapping deflection area of at least 9 cm² on the substrate surface for the first electron beam 111 and for the second electron beam 112. In other words, the first electron beam and the second electron beam can be deflected subsequently to the same positions on the substrate in a deflection area of at least 9 cm² with the deflector arrangement 130, without a movement of the stage. The overlapping deflection area may be at least 16 cm² in some embodiments, particularly at least 100 cm², or even at least 225 cm². For example, the beam deflector arrangement 130 may provide an overlapping deflection area for the first electron beam 111 and for the second electron beam 112, the overlapping deflection area having a dimension D1 in the x-y-plane of the substrate of at least 3 cm×3 cm, particularly at least 4 cm×4 cm, more particularly at least 10 cm×10 cm, or even at least 15 cm×15 cm.

In particular, the beam deflector arrangement 130 may enable a deflection of the first electron beam to an arbitrary position in a deflection area of at least 5 cm×5 cm on the substrate surface, and the deflector arrangement 130 may enable a deflection of the second electron beam to an arbitrary position in the same deflection area of at least 5 cm×5 cm on the substrate surface, particularly in the same deflection area of at least 10 cm×10 cm. The deflection areas provided for the first and second electron beams may overlap partially or entirely, such that the first and second electron beams can be deflected to the same surface contacts of the substrate without a substrate movement, by controlling the beam deflector arrangement 130 accordingly. A large sub-area of the substrate surface or even the whole substrate can be inspected by deflecting the first and second electron beams to respective surface contacts that may be distributed over a substrate area of at least 10 cm×10 cm, without moving the stage 105 (i.e., while leaving the substrate stationary).

Deflecting the first electron beam 111 and/or the second electron beam 112 to one or more surface contacts to be tested with the beam deflector arrangement 130 is beneficial as compared to the usage of one or more stationary electron beams. In particular, moving the stage 105 with respect to one or more stationary electron beams is time-consuming and less accurate as compared to a beam deflection. Further, the first electron beam can be quickly deflected on a surface contact several times for discharging, e.g. before and after the charging and inspection, without the need for a time-consuming back-and-forth stage movement. Further, a plurality of surface contacts can be quickly and conveniently tested in succession utilizing the first electron beam 111 that is deflected on the respective surface contacts for discharging and the second electron beam 112 that is subsequently deflected on the respective surface contacts for charging and/or probing.

According to embodiments described herein, a quick and reliable way of accurately testing a plurality of electrical connections is provided. Specifically, in the discharging phase (a), the first electron beam 111 is deflected with the beam deflector arrangement 130 such that the first electron beam 111 is focused on the first surface contact. In the charging phase (b), the second electron beam 112 is deflected with the beam deflector arrangement 130 such that the second electron beam 112 is focused on the first surface contact for charging. For inspecting the first electrical connection, signal electrons emitted from the substrate are detected with an electron detector 180, in particular during the charging phase or after the charging phase upon probing of specific surface contacts of the substrate with the second electron beam 112. The focusing and deflecting of the electron beams on different surface contacts increases the testing velocity and ensures that neighboring areas of the substrate are affected by the electron beams to a lesser extent, increasing the measurement accuracy. The discharging phases before and/or after the charging and inspection bring the respective surface contacts to a defined electric potential before and after the inspection. A large amount of densely arranged surface contacts and respective electrical connections can be tested quickly and reliably.

In some implementations, inspecting (c) includes conducting voltage contrast measurements based on the signal electrons detected upon impingement of the second electron beam 112 on the substrate. In particular, the second electron beam 112 can be used both for charging the first surface contact and for probing further surface contacts that ought to be electrically connected to or electrically separated from the first surface contact. Alternatively, the first electron beam 111 may be used both for discharging and for probing of surface contacts that are charged with the second electron beam 112.

In particular, inspecting (c) may include probing any one or more of the following surface contacts with the second electron beam 112 after the charging of the first surface contact 21 with the second electron beam 112: the first surface contact 21, one or more second surface contacts 22 that ought to be electrically connected to the first surface contact 21 via the first electrical connection 20, and one or more third surface contacts 23 that ought to be electrically separated from the first surface contact 21.

The first surface contact 21 may be probed for determining a charging state of the first electrical connection 20 after or during the charging. For example, an unexpectedly high electric potential of the first surface contact 21 after (or already during) the charging may be an indication of a defective (open) first electrical connection, because the applied charges cannot flow from the first surface contact 21 into the substrate toward one or more second surface contacts 22.

The one or more second surface contacts 22 that ought to be electrically connected to the first surface contact 21 via the first electrical connection 20 may be probed in order to determine whether the first electrical connection 20 actually extends between the first surface contact 21 and the one or more second surface contacts 22. If the one or more second surface contacts 22 are not charged after the charging of the first surface contact 21, the first electrical connection is probably defective (open).

The one or more third surface contacts 23 that ought to be electrically separated from the first surface contact 21 may be probed in order to determine whether the first electrical connection 20 is shorted to an adjacent electrical connection. Specifically, if one or more third surface contacts 23 are charged after the charging of the first surface contact 21, the first electrical connection is probably shorted to another electrical connection.

In some embodiments, which can be combined with other embodiments described herein, the apparatus 100 includes a two-beam column 110 that provides a common electron beam path 115 for the first electron beam 111 and for the second electron beam 112. In particular, in the discharging phase (a), the first electron beam 111 may propagate along the common electron beam path 115 through the two-beam column 110, while the second electron beam is deselected, and in the charging phase (b), the second electron beam 112 may propagate along the common electron beam path 115 through the two-beam column 110, while the first electron beam is deselected.

FIG. 1 shows an apparatus 100 with a two-beam column 110. The two-beam column 110 may include a beam selector 150 for selecting one of the first electron beam 111 and the second electron beam 112 for propagation through the two-beam column toward the substrate. For example, the beam selector 150 may include a beam blanker and/or a beam dump configured to block a deselected one of the first and second electron beams and to allow a selected one of the first and second electron beams to pass along the common electron beam path 115.

A plurality of beam optical components for influencing the selected one of the first electron beam 111 and the second electron beam 112 may be provided along the common electron beam path 115. Specifically, a focusing lens arrangement 140 and/or a beam deflector arrangement 130 may be centered with respect to the common electron beam path 115, as is schematically depicted in FIG. 1.

The beam deflector arrangement 130 may be configured to deflect a selected one of the first and second electron beams to a predetermined position on the substrate. In particular, the beam deflector arrangement 130 may provide an overlapping deflection area of at least 9 cm² on the substrate for the first electron beam 111 and the second electron beam 112.

The controller 161 may be configured to control the beam selector 150, the beam deflector arrangement 130 and/or the focusing lens arrangement 140 such that a selected one of the first and second electron beams is focused and deflected on a predetermined position of the substrate surface, such as on the first surface contact or on another surface contact. The controller 161 may be further configured to control the beam selector 150 to select the first electron beam 111 for discharging (a) and the second electron beam 112 for charging (b). The first electron beam 111 or the second electron beam 112 may be selected for probing one or more surface contacts for inspecting the respective electrical connections.

Providing a two-beam column 110 with a common electron beam path 115 for the first electron beam 111 and the second electron beam 112 may be beneficial because a large overlapping deflection area enabled by one common beam deflector arrangement can be provided, since the common electron beam path 115 has the beam deflector arrangement 130 for both beams centered in relation thereto (see FIG. 1). For example, a large deflection area having a dimension D1 of 3 cm or more, particularly 5 cm or more, or even 10 cm or more, in x- and/or y-directions can be provided. A large sub-area of the substrate or the whole substrate can be inspected without a time-consuming stage movement. In particular, the beam deflector arrangement 130 may provide an overlapping deflection area of at least 3 cm×3 cm on the substrate surface, particularly at least 5 cm×5 cm.

The beam deflector arrangement 130 may be configured to electrostatically and/or electrically deflect the first electron beam for discharging and the second electron beam for charging on a predetermined surface contact.

In some embodiments, which can be combined with other embodiments described herein, the first electron beam 111 is generated by a first electron source 121 having a first emission tip and a first extractor electrode, and/or the second electron beam 112 is generated by a second electron source 122 having a second emission tip and a second extractor electrode. The first and second electron sources may, for example, be thermal field emitters (TFE).

The electron energy of the first electron beam 111 can be appropriately set by applying a first potential to the first emission tip, and the electron energy of the second electron beam 112 can be appropriately set by applying a second potential to the second emission tip. The second potential may be set such that the second electron beam has a higher electron energy than the first electron beam, in particular a second electron energy of 5 keV or more and 15 keV or less.

In some embodiments, which can be combined with other embodiments described herein, the apparatus 100 includes an electron detector 180 for detecting signal electrons emitted from the substrate, particularly upon impingement of the second electron beam 112 on the substrate. The signal electrons may include secondary electrons (SEs) and/or backscattered electrons (BSEs).

In some embodiments, the electron detector 180 includes an Everhard-Thornley detector. The Everhard-Thornley detector may be arranged downstream of the focusing lens arrangement 140 and downstream of the beam deflector arrangement 130 in the propagation direction of the first and second electron beams, as it is schematically depicted in FIG. 1. This increases the detection efficiency.

An energy filter for the signal electrons 113 may be arranged in front of the electron detector 180, particularly in front of the Everhard-Thornley detector. The energy filter may include a grid electrode configured to be set on a predetermined potential. The energy filter may allow the suppression of low-energy signal electrons. The energy filter may be set for optimum voltage contrast detection. Accordingly, the signal current detected by the electron detector 180 may depend on the energy of the signal electrons which indicates if a probed surface contact point is provided at a predetermined electric potential or not.

An analysis unit 181 may be provided for inspecting the first electrical connection 20 connected to the first surface contact 21 based on the signal electrons detected by the electron detector 180. For example, the analysis unit 181 may provide an output indicative of a state of a plurality of electrical connections, for example “defective” or “not defective” for each of the plurality of electrical connections. Optionally, the type of defect (such as “open” defect or “short” defect) can be determined by the analysis unit 181 based on the electron signal detected upon probing of a specific surface contact.

In some embodiments, one or more further beam-optical components 171 for influencing the first electron beam and/or the second electron beam may be provided at the common electron beam path 115, such as, for example, a condenser lens arrangement and/or an aberration corrector arrangement, such as a stigmator, chromator and/or another aberration corrector.

In some embodiments, the substrate 10 is a packaging substrate configured to provide a multi-device in-package-interconnection, the first electrical connection 20 being a device-to-device electrical interconnect path. In particular, the substrate 10 may be an advanced packaging (AP) substrate, a panel level packaging (PLP) substrate, a wafer level packaging (WLP) substrate, or a micro-LED substrate.

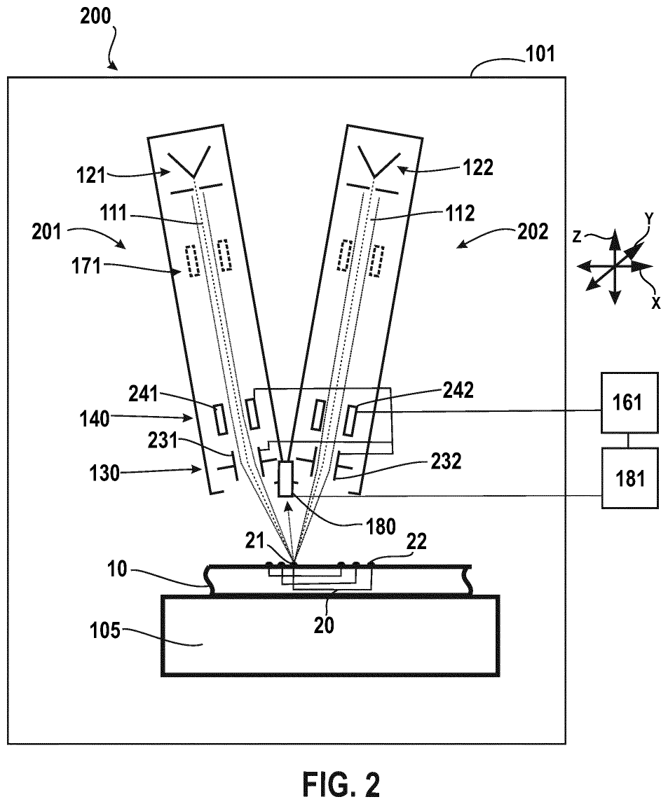

FIG. 2 shows a schematic sectional view of an apparatus 200 for testing electrical connections of a substrate 10 according to embodiments described herein. The apparatus 200 may be similar to the apparatus 100 shown in FIG. 1 and may include corresponding features, such that reference can be made to the above explanations, which are not repeated here. The differences will be explained in the following.

The apparatus 200 includes a vacuum chamber 101 that houses a stage 105 for placing the substrate 10 thereon, a first electron source 121 for generating the first electron beam 111 having the first electron energy, and a second electron source 122 for generating the second electron beam 112 having the second electron energy. The apparatus 200 further includes a focusing lens arrangement 140 for focusing a selected one of the first electron beam 111 and the second electron beam 112 on the substrate as well as a beam deflector arrangement 130 for deflecting the selected one of the first electron beam 111 and the second electron beam 112 on the first surface contact 21. Specifically, the first electron beam 111 can be deflected on the first surface contact 21 for discharging the first surface contact 21 in the discharging phase (a), and the second electron beam 112 can be deflected on the first surface contact 21 for charging the first surface contact 21 in the charging phase (b). Reference is made to the above explanations, which are not repeated here.

The apparatus 200 further includes an electron detector 180 for detecting signal electrons emitted from the substrate, particularly upon impingement of the second electron beam 112 that may be used for probing surface contacts after the charging, and an analysis unit 181 for inspecting the first electrical connection 20 that extends from the first surface contact 21 based on the detected signal electrons.

In some embodiments, which can be combined with other embodiments described herein, the apparatus 200 includes a first beam column 201 for the first electron beam 111 and a second beam column 202 arranged next to the first beam column 201 for the second electron beam 112. Each of the first and second beam columns may provide a respective beam path for the respective electron beam, such that the first and second electron beams propagate along different beam paths through a respective beam column, before the first and second electron beam are focused and deflected in succession on the first surface contact and/or on further surface contacts.

The beam deflector arrangement 130 may include a first beam deflector 231 provided in or below the first beam column 201 for deflecting the first electron beam 111 to a predetermined position on the substrate surface and a second beam deflector 232 provided in or below the second beam column 202 for deflecting the second electron beam 112 to a predetermined position on the substrate surface. The first beam deflector 231 and/or the second beam deflector 232 may be electrostatic and/or magnetic beam deflectors enabling a deflection of the respective electron beam in two directions, i.e. in x- and y-directions that define the substrate plane. The first electron beam 111 and the second electron beam 112 can be deflected to the same positions in a deflection area, without a movement of the stage. Specifically, the first beam column 201 and the second beam column 202 may be arranged in close proximity to each other, such that the first beam deflector 231 and the second beam deflector 232 provide an at least partially overlapping deflection area, within which the first and second electron beams can be deflected to an arbitrary surface contact, of at least 3 cm×3 cm, particularly of at least 4 cm×4 cm, more particularly at least 10 cm×10 cm, or even at least 15 cm×15 cm.

In some embodiments, the first beam column 201 and the second beam column 202 may be arranged adjacent to each other and may be tilted toward each other (see FIG. 2). For example, the first electron beam path defined by the first beam column 201 and the second electron beam path defined by the second beam column 202 may enclose an angle of 5° or more and 45° or less with respect to each other, as it is schematically depicted in FIG. 2. A tilting of the first and second beam columns toward each other can increase the overlapping deflection area provided by the beam deflector arrangement 130 that includes the first beam deflector 231 and the second beam deflector 232, even if the first and second beam deflectors are located spaced apart from each other in two adjacent beam columns.

The focusing lens arrangement 140 may include a first focusing lens 241 provided in or below the first beam column 201 for focusing the first electron beam 111 propagating along a first electron beam path defined by the first beam column 201 and a second focusing lens 242 provided in or below the second beam column 202 for focusing the second electron beam 112 propagating along a second electron beam path defined by the second beam column 202. The first focusing lens 241 and/or the second focusing lens 242 may be a magnetic objective lens and/or an electrostatic objective lens, respectively. For example, the first focusing lens 241 and/or the second focusing lens 242 may include a magnetic lens component and/or an electrostatic lens component. In other embodiments, purely magnetic objective lenses or purely electrostatic objective lenses that respectively include one or more electrodes may be provided for focusing the electron beams on the substrate surface.

In some embodiments, the first focusing lens 241 may include a first main focus lens and a first refocus lens, e.g. an auxiliary focusing coil. The first refocus lens may be configured to ensure that the first electron beam 111 is focused on the surface of the substrate, even in the case of a large deflection angle applied by the first deflector 231. For example, the first refocus lens may be able to apply a focus correction that is dependent on the deflection angle applied by the first deflector 231, reducing or preventing a deflection-dependent spot size or spot shape. Alternatively or additionally, the second focusing lens 242 may include a second main focus lens and a second refocus lens, e.g. an auxiliary focusing coil. The second refocus lens may be configured to ensure that the second electron beam 112 is focused on the surface of the substrate, even in the case of a large deflection angle applied by the second deflector 232.

A controller 161 may be configured to control the apparatus 200 such that, in the discharging phase (a), the first electron beam 111 is focused and deflected on the first surface contact to discharge the first surface contact 21, particularly with the first focusing lens 241 and the first beam deflector 231. The second electron beam 112 may be deselected, e.g. blanked, blocked, or shut off in the discharging phase (a).

The controller 161 may be configured to control the apparatus 200 such that, in the charging phase (b), the second electron beam 112 is focused and deflected on the first surface contact to charge the first surface contact 21, particularly with the second focusing lens 242 and the second beam deflector 232. The first surface contact may be brought to a predetermined electric potential by charging. The first electron beam 111 may be deselected, e.g. blanked, blocked, or shut off in the charging phase (b).

The controller 161 may be further configured to control the apparatus 200 such that, subsequent to or during the charging phase (b), the first electrical connection is inspected by detecting signal electrons emitted from the substrate with the electron detector 180. For example, signal electrons may be detected during probing of the first surface contact 21, one or more second surface contacts 22, and/or one or more third surface contacts 23 with the second electron beam 112.

Providing two separate beam columns for the first electron beam and for the second electron beam may be beneficial, because the control of the beam selection, beam deflection and beam focusing is less complex and faster as compared to one two-beam column that is adapted for deflecting and focusing both electron beams in succession to predetermined surface contacts. A large overlapping deflection area may also be possible, if the first beam column 201 and the second beam column 202 are located in close proximity to each other. For example, the first and second electron beam paths defined by the first and second beam columns may have a distance of 5 cm or less, particularly 3 cm or less from each other. In addition, the first and second beam columns can be tilted toward each other, in order to yet further increase an overlapping deflection area. A large overlapping deflection area of, e.g., 25 cm² or more, 100 cm² or more, or even 225 cm² or more is possible.

In some embodiments, one or two further electron beam columns (e.g., configured to generate an electron beam for discharging and an electron beam for charging) may also be arranged on the other side the substrate, such that surface contacts on the first surface and on the second surface of the substrate can be discharged and/or charged. For example, electrical connections that connect surface contacts on different sides of the substrate can be inspected.

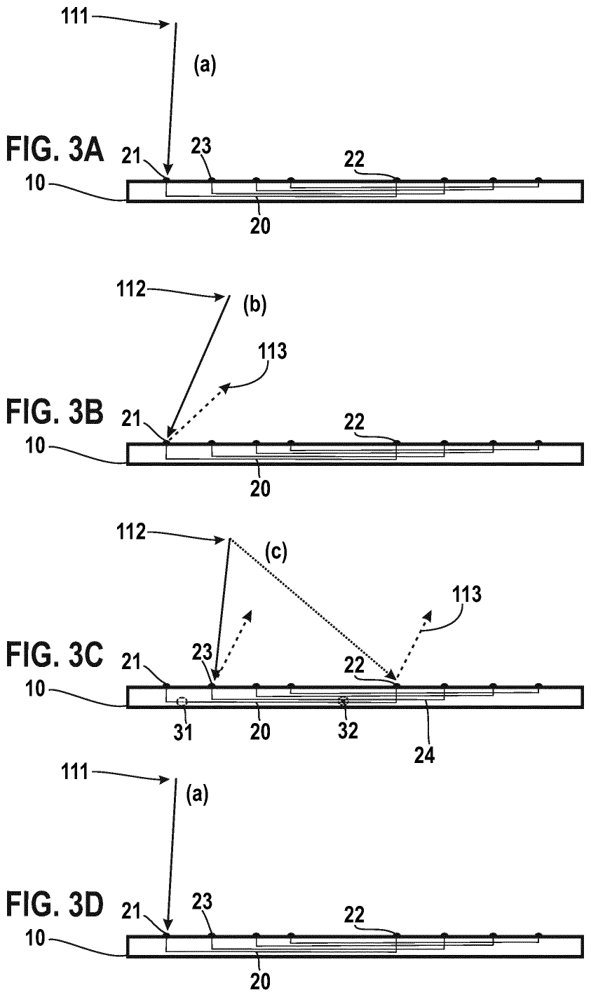

FIGS. 3A-D schematically illustrate a testing method according to embodiments described herein. The illustrated testing method can be conducted with any of the apparatuses described herein.

In FIG. 3A, a discharging phase (a) is illustrated. The first electron beam 111 having an electron energy suitable for removing negative charges is focused and deflected on the first surface contact 21 for removing negative charges that may be present on the first surface contact 21 and on the first electric connection 20 extending therefrom.

In FIG. 3B, a charging phase (b) is illustrated. The second electron beam 112 having an electron energy suitable for applying negative charges is focused and deflected on the first surface contact 21 for setting the first electrical connection 20 on a predetermined electric potential that allows voltage contrast measurements to be subsequently conducted. Since the first surface contact 21 has been previously discharged in the discharging phase (a), an amount of negative charges that accurately corresponds to a predetermined electric potential can be applied with the second electron beam 112. Since the second electron beam 112 is focused and deflected on the first surface contact, the charging of a surrounding substrate area can be reduced or avoided. Optionally, signal electrons 113 can be detected already during the charging phase (b) for checking and/or monitoring, if the secondary electron signal during the charging behaves in an expected way. Notably, already the secondary electron signal during the charging can be indicative of a defect. Specifically, if the first surface contact 21 charges up faster than expected, an “open” defect may be identified, and if the first surface contact 21 charges up slower than expected, a “short” defect may be identified.

In FIG. 3C, an inspection phase (c) is illustrated. The second electron beam 112 probes any one or more of the following surface contacts: The first surface contact 21, one or more second surface contacts 22 that ought to be electrically connected to the first surface contact 21, and/or one or more third surface contacts 23, particularly of neighboring electrical connections, that ought to be electrically separated from the first surface contact 21. Signal electrons 113 are detected during the probing.

An “open” defect 31 in the first electrical connection 20 is identified if the second surface contact 22 is not charged, which can be detected by probing the second surface contact 22. A “short” defect 32 between the first electrical connection 20 and a second electrical connection 24 is identified if the third surface contact 23 is charged, which can be detected by probing the third surface contact 23. In particular, a plurality of surface contacts can be probed for identifying, whether the respective charging state of the plurality of surface contacts is correct and as expected.

After the inspection, in FIG. 3D, another discharging phase (a) is illustrated. The first electron beam 111 having the first electron energy suitable for removing negative charges is focused and deflected (again) on the first surface contact 21 for removing the previously applied negative charges from the first surface contact 21. A negative effect of previously applied charges on subsequent measurements can be reduced or avoided. The removal of charges from the first surface contact 21 after the inspection may conclude the testing of the first electrical connection 20.

Thereafter, a second electrical connection 24 that extends from a second surface contact 22 may be analogously inspected.

A plurality of further electrical connections that extend from a plurality of surface contacts may then be analogously inspected, particularly 1.000 or more, or even 1.000.000 or more electrical connections may be tested in succession.

Since the beam deflector arrangement 130 provides a large overlapping deflection area for the first and second electron beams, a plurality of electrical connections can be inspected without a movement of the substrate, purely by deflecting the first and second electron beam in succession on the plurality of surface contacts. The testing speed and the testing accuracy can be improved in relation to other methods that may rely on substrate movements and/or electron flood guns for charging.

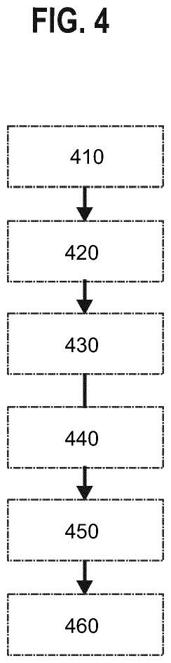

FIG. 4 shows a flowchart of a method of testing electrical connections of a substrate according to embodiments described herein.

In box 410, a substrate with a plurality of surface contacts and a plurality of electrical connections extending therefrom is placed on a stage in a vacuum chamber. The substrate may be an advanced packaging substrate or a panel level packaging substrate.

In box 420, negative charges are removed from a first surface contact of the substrate by focusing and deflecting a first electron beam having a first electron energy on the first surface contact.

In box 430, negative charges are applied to the first surface contact by focusing and deflecting a second electron beam having a second electron energy on the first surface contact. The first surface contact and the first electrical connection extending therefrom are set on a predetermined electric potential by focusing and deflecting the second electron beam over a predetermined time on the first surface contact.

In box 440, the first electrical connection is inspected by detecting signal electrons emitted from the substrate, particularly upon impingement of the second electron beam during or after the charging. As mentioned above, boxes 430 and 440 may happen simultaneously or subsequently.

In box 450, previously applied negative charges are removed from the first surface contact with the first electron beam.

Notably, in some embodiments described herein, one of the discharging phases (i.e. box 420 or box 450) may be omitted. For example, in some embodiments, it may be sufficient to discharge the first surface contact after the inspection.

In box 460, a plurality of further electrical connections may be inspected analogously by deflecting the first and second electron beams in succession on the surface contacts from which the further electrical connections extend.

While the foregoing is directed to some embodiments, other and further embodiments may be devised without departing from the basic scope thereof, and the scope thereof is determined by the claims that follow.

1. A method for testing electrical connections of a substrate, the substrate having a first surface contact and a first electrical connection extending from the first surface contact, the method comprising:
(a) discharging the first surface contact by focusing and deflecting a first electron beam having a first electron energy on the first surface contact;
(b) charging the first surface contact by focusing and deflecting a second electron beam having a second electron energy different from the first electron energy on the first surface contact; and
(c) inspecting the first electrical connection by detecting signal electrons emitted from the substrate.

2. The method of claim 1, wherein (a) is conducted before (b), and wherein (a) is again conducted after (c).

3. The method of claim 1, wherein (a), (b)+(c), and optionally again (a), are conducted in this order for each surface contact of a plurality of surface contacts of the substrate for inspecting a plurality of electrical connections connected to the plurality of surface contacts.

4. The method of any of claims 1, wherein a plurality of surface contacts are distributed over a substrate surface area of at least 9 cm², and the first and second electron beams are deflected successively on the plurality of surface contacts with a beam deflector arrangement, without a movement of the stage.

5. The method of claim 1, wherein the first electron energy is lower than the second electron energy, wherein the first electron energy is between 1 keV and 3 keV and the second electron energy is between 5 keV and 15 keV.

6. The method of claim 1, wherein (c) comprises conducting voltage contrast measurements based on the signal electrons detected upon impingement of the second electron beam or the first electron beam on the substrate.

7. The method of any of claims 1, wherein (c) comprises probing any one or more of the following surface contacts with the second electron beam or the first electron beam after the charging of the first surface contact with the second electron beam:
the first surface contact;
one or more second surface contacts that ought to be electrically connected to the first surface contact via the first electrical connection; and
one or more third surface contacts that ought to be electrically separated from the first surface contact.

8. The method of any of claims 1, wherein
in (a), the first electron beam propagates along a common electron beam path through a two-beam column while the second electron beam is deselected; and
in (b), the second electron beam propagates along the common electron beam path through the two-beam column while the first electron beam is deselected.

9. The method of any of claims 1, wherein
in (a), the first electron beam propagates through a first beam column, is focused with a first focusing lens of the first beam column, and
is deflected on the first surface contact with a first beam deflector of the first beam column; and
in (b), the second electron beam propagates through a second beam column, is focused with a second focusing lens of the second beam column, and
is deflected on the first surface contact with a second beam deflector of the second beam column.

10. The method of claim 9, wherein the first beam column and the second beam column are arranged next to each other and are tilted toward each other.

11. The method of any of claim 1, wherein the first electron beam is generated by a first electron source having a first emission tip provided on a first potential, and the second electron beam is generated by a second electron source having a second emission tip provided on a second potential.

12. The method of any of claim 1, wherein the substrate is a packaging substrate configured to provide a multi-device in-packageinterconnection, the first electrical connection being a device-to-device electrical interconnect path, the substrate being an advanced packaging (AP) substrate, a panel level packaging (PLP) substrate, a wafer level packaging (WLP) substrate or a micro-LED substrate.

13. An apparatus for testing electrical connections of a substrate, comprising:
(a) vacuum chamber that houses a stage for placement of a substrate;
a first electron source configured to generate a first electron beam having a first electron energy;
a second electron source configured to generate a second electron beam having a second electron energy different from the first electron energy; and a controller configured to control the apparatus such that:
in a discharging phase (a), the first electron beam is focused and deflected on a first surface contact to discharge the first surface contact;
in a charging phase (b), the second electron beam is focused and deflected on the first surface contact to charge the first surface contact; and
a first electrical connection connected to the first surface contact is inspected by detecting signal electrons emitted by the substrate with an electron detector during or after the charging phase (b).

14. The apparatus of claim 13, comprising a two-beam column providing a common electron beam path for the first electron beam and the second electron beam, the two-beam column comprising a beam selector for selecting one of the first electron beam and the second electron beam for propagation through the two-beam column toward the substrate.

15. The apparatus of claim 13, comprising a first beam column with a first focusing lens and a first beam deflector for focusing and deflecting the first electron beam and a second beam column with a second focusing lens and a second beam deflector for focusing and deflecting the second electron beam, the first beam column and the second beam column arranged next to each other.

16. The apparatus of claim 13, comprising a beam deflector arrangement configured to deflect a selected one of the first and second electron beams to a predetermined position on the substrate and/or a focusing lens arrangement configured to focus the selected one of the first and second electron beams on the substrate.

17. The apparatus of claim 16, wherein the beam deflector arrangement provides an overlapping deflection area for the first electron beam and for the second electron beam of at least 9 cm² on the substrate.

18. The apparatus of any of claim 13, wherein, for inspecting the first electrical connection, the second electron beam is focused and deflected on at least one of the first surface contact, one or more second surface contacts that ought to be electrically connected to the first surface contact, and one or more third surface contacts that ought to be electrically separated from the first surface contact, and the signal electrons respectively emitted by the substrate are detected with the electron detector for conducting voltage contrast measurements.

19. An apparatus for testing electrical connections of a substrate, comprising:
a vacuum chamber that houses a stage for placement of a substrate;
a. first electron source configured to generate a first electron beam having a first electron energy;
a second electron source configured to generate a second electron beam having
a second electron energy different from the first electron energy;
a focusing lens arrangement configured to focus the first electron beam on the substrate in a discharging phase and to focus the second electron beam on the substrate in a charging phase;
a beam deflector arrangement configured to deflect the first electron beam on a first surface contact of the substrate to discharge the first surface contact in the discharging phase and to deflect the second electron beam on the first surface contact to charge the first surface contact in the charging phase;
an electron detector for detecting signal electrons emitted from the substrate; and an analysis unit for inspecting a first electrical connection extending from the first surface contact based on the signal electrons.
